(19) United States
(12) Patent Application Publication
(10) Pub. No.: US 2014/0214354 A1
(43) Pub. Date: Jul. 31, 2014

(54) SYSTEM AND METHOD OF DETECTION AND ANALYSIS FOR SEMICONDUCTOR CONDITION PREDICTION

(71) Applicant: Verayo, Inc., San Jose, CA (US)

(72) Inventors: Henry Nardus Dreifus, Sanford, FL (US); Meng-Day Mandel Yu, Fremont, CA (US)

(21) Appl. No.: 14/165,567

(22) Filed: Jan. 27, 2014

Related U.S. Application Data
(60) Provisional application No. 61/757,468, filed on Jan. 28, 2013.
(60) Provisional application No. 61/799,667, filed on Mar. 15, 2013.

(51) Int. Cl. G01R 31/26

(52) U.S. Cl. CPC G01R 31/2607
USPC 702/117

(57) ABSTRACT

The invention described here enables in-operation, low-cost, non-invasive measurement of component performance and condition for assessing device longevity prediction, resilience and reliability. The non-invasive component measurements to be performed and subsequently evaluated are based on at least a set of physically unclonable functions and other measurements which can be error corrected, and the error correction factor and other measurements provides insight to the device condition. The system as well is adaptive and allows the introduction of new measurements across not only similar components but to include the family of components similarly fabricated.

### CROSS-REFERENCE TO RELATED APPLICATIONS

This application claims priority under 35 USC 119 to U.S. Provisional Application Ser. No. 61/757,468 (Attorney Docket No.: VER-014PRV) filed on Jan. 28, 2013, titled AUTOMATED METHOD OF DETECTION AND ANALYSIS FOR SEMICONDUCTOR CONDITION PREDICTION AND SYSTEM and U.S. Provisional Application Ser. No. 61/799,667 (Attorney Docket No.: VER-014PRV1) filed on Mar. 15, 2013, titled AUTOMATED METHOD OF DETECTION AND ANALYSIS FOR SEMICONDUCTOR CONDITION PREDICTION AND SYSTEM, the entire disclosures of which are incorporated herein by reference.

### FIELD OF THE INVENTION

This invention is related to computer systems and, more specifically to device performance measurement for integrated circuit to assess operating condition, longevity and performance related issues.

### BACKGROUND

Known techniques teach both invasive and non-invasive measures of performance including direct accelerated and destructive testing. These results are used to determine properties such as mean-time between failures of devices, and are used, for example, to overhaul microelectronic systems based on regular intervals. For Example, research by Xie and Pecht, entitled Applications of In-Situ Health-Monitoring and Prognostic Sensors, and others at the CALCE Electronic Products and Systems Center at the University of Maryland teach the benefits and proffer models for monitoring the health of/in electronics. This research is based on the predicted undertaking of a linear or measureable decay indication model to better predict a component's life expectancy. As a descriptive framework, this art describes two of the techniques—(1) in circuit evaluation and (2) weak-circuit failure. The state of the current art does not address and teaches away from the measurements of a device baseline given the unique nature of each device or component.

The approach of known systems and methods does not accommodate the natural manufacturing variations that each individual electronic component or device includes or expresses. These variations are due to minute variations in both the manufacturing process as well as provide for a robust way to uniquely an electronic component. The known “Physics of Failure” approach does not anticipate or accommodate such individual device “starting point” differences (e.g. each and every electronic component is in reality is commencing its life from a different baseline, and as such will have by definition achieve a potential different life-span, just as people have varying lifespans due to many factors). As will be discussed in detail below, the assumption that the baseline of every component starts out “the same” is not correct.

As such, this approach for a “physics of failure” model is based on an assumption of a predicted and common path to fail, from a common starting point. Furthermore, the ability to accurately test and measure reliability of components or devices is even more critical in application that require very high-reliability or use in extreme environments, difficult to replace (such as embedded in medical implanted devices), deployed into space, used deep underwater, or operated in very high and very low temperatures and pressures. Therefore, what is needed is a system and method that performs measurements that assess operation, longevity, and performance of a device or electronic component.

### SUMMARY

The present invention is directed at a system and method that encompasses embodiments for multi-dimensional automated computer-analyzed device performance measurement of various discrete condition aspects of a component such as a semiconductor, expressed by example in an integrated circuit, to assess operating conduction, longevity and performance related issues. In accordance with the various embodiment of the present invention, the system and methods can provide real-time diagnostic feedback on the state of a device and improved prediction of device performance including early failure detection.

The sensing measurement methodology of the present invention applies an ability to converge discrete orthogonal parasitic and non-parasitic sensor modes including a set of at least one parametric monitors such as current, and weak or threshold circuits that would fail as a device ages or degrades couple with a set of at least one unclonable functions versus a single methodology that cannot only accomplish this but also assert a device's unique identity. This coupled with the baseline of the unclonable functions which assert the correcting and other vectors can help to quantify not only a component's “starting point' but as well aver the validity and identity of the component. The instant invention further improves upon prior techniques in a number of ways including integrating the measurements of multiple dimensions of parameters, establishing and accumulating longitudinal monitoring, and a correction vector/factor and compares both individually and combined measurements to aver device condition such as from a reference starting point to establish a component's age, or relative age against a set of devices. Further, through the introduction and application of one or more predictive algorithmic correction(s), such as Kalman filtering, hidden Markov modeling and other techniques across a longitudinal time-series sequence of measurements, can improve the fidelity and correct for inaccuracies in the acquisition and measurement of a specific measurement or sequence of measurements.

### BRIEF DESCRIPTION OF THE DRAWINGS

FIG. 1 shows a high-level overview of the major components of the system in accordance with various aspects of the present invention.

FIG. 2 shows a high-level flow diagram of the component processes for the measurement and data acquisition in accordance with various aspects of the present invention.

FIG. 3 shows a high-level flow representation of the measurement processing and analysis performed within this application of the present invention in accordance with various aspects of the present invention.

FIG. 4 shows a block diagram of the associated algorithmic processing elements comprising the analysis modules incorporated within the in-operation analysis portion of the system presented including the multi-factor/multi-measurement calculations in accordance with various aspects of the present invention.

FIG. 5 shows a device registration process in accordance with the various aspects of the present invention.

### DETAILED DESCRIPTION

The present invention and its various aspects are related, but not limited, to the unique and cumulative measurement and assessment of certain selected difficult to clone performance elements embedded into and on an electronic component to improve the detection of device lifetime and reliability performance degradation compared against an adjusted or normalized predicted device lifetime. Just as there are no identical snowflakes, no two electronic components are exactly the same. Although designed to be highly similar, minute variances in fabrication, and packaging/construction, topology and concentration of impurities and other variations exist in every electronic component. This is due to a number of factors including trace impurities in the base materials, microscopic structural variations such as minute cracks and other natural or introduced variations in substrates, slightly different temperatures and process and handling times in the multi-stage process of component fabrication, slight differences in densities of materials applied during deposition stages, light, etching, washing, etc.

The preferred practice of a device condition screening and analysis is based on a simplified and streamlined approach through the acquisition of specific and determined measurement criteria established through building an understanding based on pre-existing behavior characteristics of semiconductor properties over time. The preferred embodiment is based on a solution that includes an electronic component device with a set of least one specific circuit blocks designed to perform certain specific device condition assessment functions which are associated with a back-end database and data analysis processing framework that evaluates, assesses and reports discrete circuit device element condition, integrated condition across a set of at least one condition element as well as continuously improve with assessment fidelity, based on intra- and inter-depth and breadth of measurement, testing and evaluation cumulatively over time across a component device and family of components with similar physical characteristics.

Further, post-manufacturing the storage (inactive) and use of the component (active) under normal and extra-normal (very high temperatures, very low temperatures, radiation exposure, high g-force vibrations, voltage and current variations, both in and outside of design specification envelopes, exposure to chemicals (as in the environment), including impurities in the device packaging, adhesives, etc.) introduce or exacerbate these minute variations. Although very small and barely detectable, when these and other factors are combined, this can have a statistically significant, detectable impact and affect the characteristic specific performance of any individual component or device that is manufactured. Further, through the normal (and abnormal) everyday use, components do age, and this age, like in people, takes its toll on longevity and performance. Just as human beings “slow down”, so do electronic components, over time as they get old. Depending on usage, and environment, all components can and do age slightly differently (just like people do).

Design and fabrication engineers understand this variation challenge, and take great efforts to overcome as many of these factors and design extra safety margins in the development of electronic component manufacturing processes. It is customary to build in and establish wide safety margins across the entire life cycle, from the basic building blocks (e.g. the geometries of the building blocks) that become reflected in the “design rules” which form the basis for the rendering of the individual circuits to describe feature sizes, data paths and line widths individual and collective gate and features, distances between features including maxima for component densities, and other design constraints and aspects to accommodate a reliable and predictable outcome for these variations. Manufacturers pride themselves on mass production and achieving scale economies to result in cost effective volume components to deliver cost efficient electronic products. These design safety margins, which become the semiconductor manufacturer's “design rules” are a balance “trade off” between consuming extra space (which is costly) to achieve a reliable level of operation with an acceptable mean time between failures (MTBF) of that device. The result is a way for engineers to build parts that operate within the best trade-off between reliable performance and space/size of the semiconductor against a specified operating lifetime of the component for a given specified operating environment/regime.

This invention is based on the development of emplacing a certain type of difficult to clone ‘threshold’ electronic elements that will be most sensitive to the changes in performance of a device throughout its lifetime. Over time, a device will degrade in its performance, as it is cycled and used in normal, and outside of normal operating conditions, and no two devices will behave, or degrade exactly the same. Just as with human beings, as they age, they will encounter differences over time. Being able to detect these changes using threshold and other circuits, with geometries well inside the established “safety margin” design rules, offers the ability to develop insights on a specific component and determine a number of insights including a specific component's resilience, age, and longevity. As well, the very same methods and processes can be configured to alert an impending device failure, prior to failing, analogous to a “check engine” indicator light on an automobile.

The process of evaluating the ways and means of a semiconductor component's life is to evaluate simultaneously multiple dimensions of a component's behavior over time. Accumulating the measurements and failure profiles provides a more detailed collective understanding of the failure trajectory, including the framework to benchmark the failure modes (commonalities) as well as failure patterns (precursors). The challenge however is with each and every semiconductor there are very slight variations, detectably different, and therefore there is the potential uncertainty for how any given electrical component might fail.

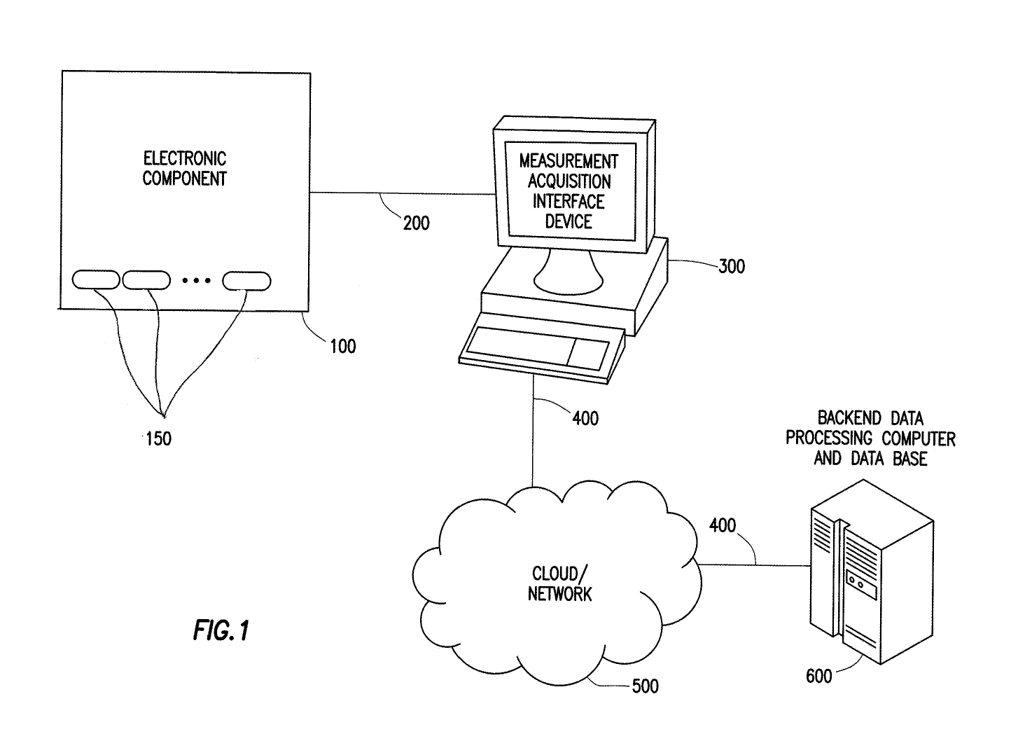

This invention leverages these minute differences and unlike the prior art, this invention teaches away from emplacing common detection circuitry, starting from a common point, but rather starting from each semiconductor's own starting point. The embodying system summarized in FIG. 1 includes an electronic component such as an integrated circuit (100) with a set of at least one circuit such as a ring oscillator delay circuit, a delay line, or a bi-stable memory component fabricated within. These circuits can be general or specifically designed, and in the latter case are created by a number of companies including Intrinsic ID Corporation, located at High Tech Campus 9, 5656 AE Eindhoven, The Netherlands, Verayo Corporation located at 1054 South De Anza Blvd, San Jose, Calif. 95129 and others.

The circuits can exist in a semiconductor mask or can be firmware/software programmable such as in a Field Programmable Gate Array (FPGA) or similar framework. We note structures such as Ring Oscillators are frequently used for process characterization and exists on many fabricated devices and such structures can be repurposed for the said uses. Products incorporating such circuits, either hardwired in the mask or programmable, or either explicitly for the said purpose or can be repurposed for the said purpose, include semiconductors fabricated by leading field programmable gate array and processor system on a chip companies, using an established and understood framework in the production process applied across the semiconductor industry. These products incorporate such circuits for other purposes and are commercially available.

The accordance with various aspects of the present invention, one embodiment of the invention is designed to be operated either directly by the individual undergoing the test (self-testing) or via an automatic means without the need for an operator, such as in an assembly or production setting. The system includes an algorithmic platform (implementable in software, firmware, or hardware, or a mixture) and cumulative underlying and continuously improving reference databases which determines the test regime as well as real-time processing and output of the test results.

Through the implementation of a physically “unclonable” function (PUF), such as a ring oscillator delay circuit or a bi-stable memory component, enables both the concurrent unique identification and the detection of an individual device's variation. The limitations however on PUF is that the variations by themselves do not in themselves provide any insights. The present invention and its various aspects use the “birth mark” manufacturing variations as a data point in helping to derive the predictive failure modes and usage of a device, since not all devices start out the same.

The PUF framework, such as US Patent Publication US 2009/0083833 (see also, U.S. Pat. No. 7,898,283 and U.S. Pat. No. 8,054,098) typically provide for an error correction factor that adjusts for “variation over time” due to degradation from aging, exposure, etc. to preserve the unique identification characteristics. The present invention, while taking advantage of unique manufacturing variations, additionally looks at stress and aging effects. In a University of Connecticut publication “CDR: Combat Die Recovery” (republished as “Identification of Recovered ICs using Fingerprints from a Light-Weight On-Chip Sensor,” IEEE/ACM Design Automation Conference (DAC), 2012 by as X. Zhang, N. Tuzzio, and M. Tehranipoor) circuits were built to detect whether a die has been recycled by looking at the age of the device. The present invention differs in that the unique “birthmark” of a device is used as a starting point in our present prediction model, and for the purpose of predictive maintenance of microelectronic systems.

Early detection of device health and performance issues can be one of the most significant contributors to increasing the life expectancy and reliability of critical electronics, such as medical devices, financial networks, communications equipment, utilities and other critical infrastructure and national defense applications. Moreover, knowing more precisely when a device will fail—rather than on relying upon traditional metrics such as Mean-Time-Between-Failure (MTBF) can change the way in which higher levels of availability can be consistently maintained, as well as only performing maintenance (or replacement) when indicated, just prior to device failure. This can save both time and money, making the “total cost of ownership” a far better value proposition, and possibly lives, as in the case of critical medical equipment. A further object of this invention is to be able to provide better feedback and insights on how a device is performing, and both individually and collectively—thus providing valuable feed back to the electronic component designers to improve their parts.

Screening for early detection can have a major impact on both the quality and quantity of any platform that incorporates this capability over a device lifetime. Such longitudinal diagnostic tests will not only result in improved reliability and longevity, but help to assure the right components are in a system. As lifespans increase due to prolonging the use of electronic equipment beyond its anticipated lifetime such as through program life extensions of major Defense and industry programs, results in equipment operating well beyond its originally envisioned useful life-span (such as aircraft, etc.). This severely increases the component health risks, including the risk of failures especially as component elements get older. Providing predictive methods to improve the ways to detect and mitigate the long term program cost impacts due to device component failures will not only save money, but provide for better availability and safer, more assured operations.

Continuing with FIG. 1, the various aspects of the present invention applies these circuits within for a different specific purpose as described below. The component device (100) includes elements (150) as discussed in detail below. The component device (100) is connected via a connection means (200), such as a cable or a wireless connection or any electromagnetic communication connection, to a local computer test station (300). The connection means (200) provides for an interface means to connect to the component device (100). The station (300) is a device that performs a variety of functions, including for example acting as a measurement acquisition interface device that is connected via a wired or wireless connection (400) either directly or through a network (500), such as the internet or private network, to a back-end host computer (600). The host computer (600) maintains the underlying databases and supports back-end analysis processes, including the ongoing analytic analysis and acceptable measurement values, and to develop continuously improving cumulative understanding of the properties of the devices.

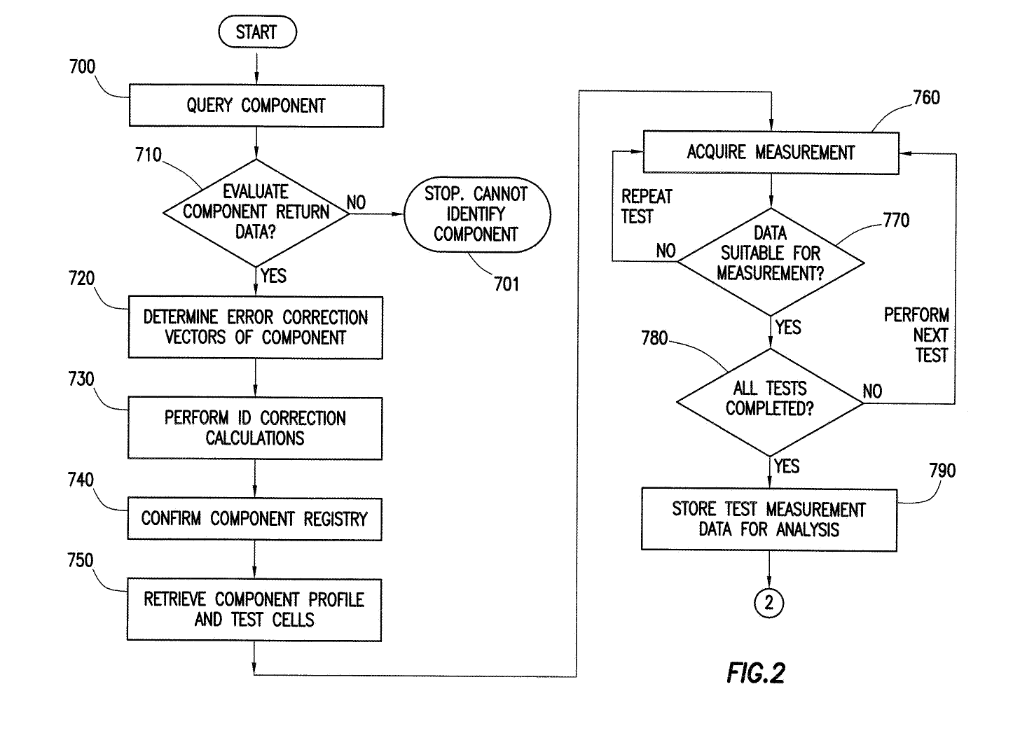

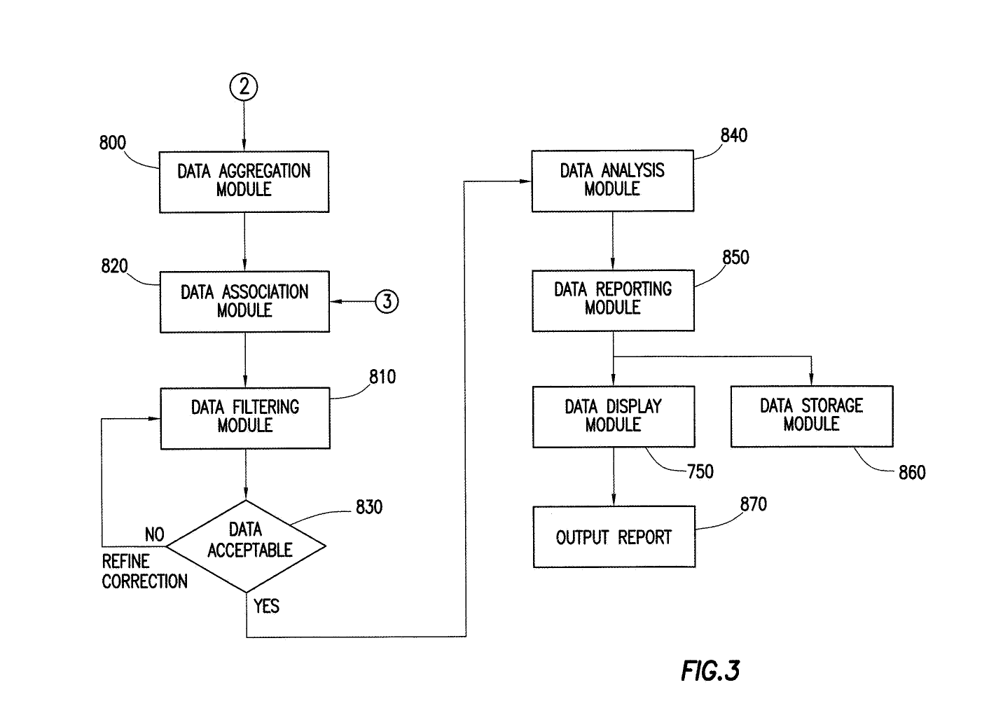

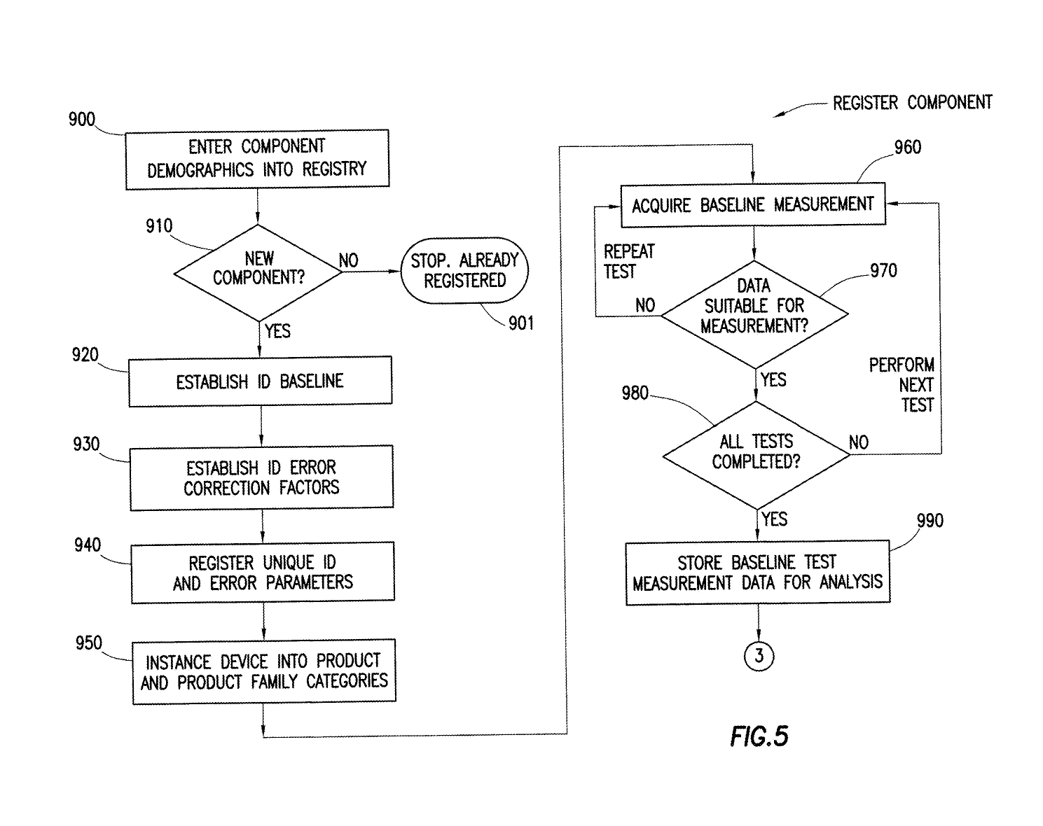

The station (300) programmatically guides the conduct of the testing process as summarized in FIGS. 2 and 3. Similarly, an instance of the station (300) is programmed to register devices as in FIG. 5. The station (300) (FIG. 1) performs a series of self-tests of the detection and integrity of the component under measurement (100). This test process queries (700) via the station (300). A resultant return data stream (710) provides a basic set of information including the device identity and other parameters. If the device (100) cannot return a value that is processed, either the device (100) is malfunctioning, or the electronic component or device (100) cannot be identified (701). In this case, the process will stop and report that it cannot identify the device (100).

Upon successfully device identification, the specific error correction vectors are extracted from the measurement process (720). In the steps above, the error correction vectors are used to help assert the unique identity of the device. A more careful evaluation is performed in (720) to extract the error values based on the identification step, through backing out the ID correction calculations in (730). This framework can be useful to overcome device variation, analogous to slight changes in a biometric measurement of a person (e.g. as features change slightly over time). The various aspects of the present invention establishes and evaluates longitudinally across a number of modalities and dimensions, error vectors being but one, and variation themselves, both in magnitude and velocity, drives this invention further beyond the prior art to develop insights beyond confirmation of device identity.

Following the correction calculation, the specific unique ID of the device can be confirmed through a database lookup (740) to confirm not only the specific component, but as well return the specific elemental profile and set of test elements (150) on the electronic component, such as device (100). These test cells or elements (150) include a set of at least one of a number of circuit blocks that provide specific parametric information to be collected starting a sequence of test inquiries to acquire measurements (760) with a resulting data integrity check (770) which will repeat the test if there is a value that is either not expected or not suitable. These test cells or elements (150) can also be rendered in software, firmware as well as hardware circuit elements or in combination thereto. In the case there is a failure of the acquisition of the measurement, this will also be noted, and the subsequent tests, as directed by the understanding of the device profile stored in the back end data base and processor, such as the host computer (600) indicates. Tests are performed and data collected until all required or necessary or selected tests are completed (780). The results are stored (790) to include tests performed, and other data including the specific test unit or station (300) that performed the test as well as date, time and other parameters.

Once all the test measurements are acquired they are collected and combined into a data aggregation module (800) which formats the data and associated parameters (820) for data filtering/correction analysis. This filtering and correction data improvement process is performed in a filtering module (810), which includes an intake process of raw measured data and other parameters including device baseline, tests performed, data collected, etc. to be applied in a comparative way against reference data that can include both the specific component device, the family of components/devices with the specific test elements (150) and family of similar electronic component devices that would incorporate similar test elements and reference data. The test data along with other baseline and reference data would be subjected to a series of comparative tests, performed either sequentially or in parallel to further refine the understanding and potentially improve the data (data correction) on an iterative basis. This data analysis can be performed either on the station (300) and/or on the backend processing engine, such as a host computer (600).

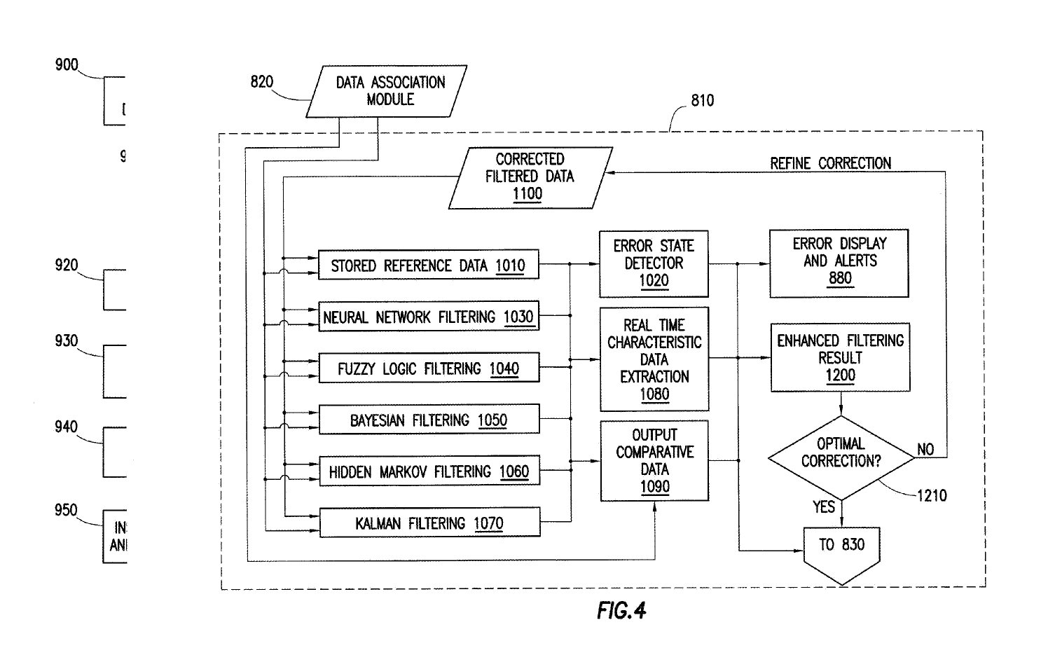

Referring now to FIG. 4, an example of the data refinement and analysis process is shown in accordance with various aspects of the present invention. This can include for example normalization across time (projecting forward and referencing backward—such as via a Bayesian methodology—to normalize against test intervals) since devices start at different baselines, and thus will have different lifetimes, apparent age, and other characteristics.

A priori, based on the type of measurement and test condition, there is no conclusive assertion on which single or combination of filtering, or set of filters as applied will result in calculating the most reliable measurement. For this reason, both the comparative data, including each of the raw datum along with the data characteristic extracted is communicated to the data association module (820) to allow longitudinal improvement of both the reference data as well as the ability to introduce new measures and tests that may be subsequently introduced. The data analysis module (840) develops not only the output analysis which is subsequently reported (850) but also maintains a record of which filtering methods applied for which tests based on the context of the unique underlying determining parameters. This can be used to refine the precision of the solution embodiment, as well as potentially, based on the accuracy of the predictive methods, synthetically determine certain test measurement values solely by calculation, thus reducing the actual number of measurements that may be needed.

Once an optimal correction (which can result in being the baseline data as well), there is a data association (820) process to connect the data to the portfolio of similar components—based on such information as lot numbers, dates of manufacture, as well as to associate across similar types of components, including variants and other devices that have similar unique elements (150) embedded within. This association incorporates baseline data achieved during a priori device registration per FIG. 5. This output (3) serves as an import to (820) with exemplar information such as described above. Upon an iterative process to goal seek the best dataset, the raw data and the accepted corrected data (830) are provided to a data analysis module (840) which would perform the comparative analysis including the anticipated lifetime using both the baseline raw data as well as the improved data as processed above. Such corrected information may include normalizing against time intervals.

The data analysis module (840) compares both intra-test and inter-test data (when available) as well as comparative analysis against corrected/adjusted baseline reference data that is coupled based on the degree of association (e.g. the exact component, components from a given production lot, similar components and the family of similar devices that have similar test elements, etc.) and such other inputs collected in (720). The data analysis is based on calculating a number of factors including the rates and vectors of change developed and measuring across the other measurement dimensions to allow data calculations of model convergence and test correlation. It is possible in the data analysis that a measurement previously accepted in (770) can be found non-conforming and this would be reported. This could also include an indicated failure of one or more the test elements (150).

Upon processing the data the results are conveyed to a data reporting module (850) to present the resulting test information in a readable format. This includes a graphical interface to a data display module (880) on the computer work station or a portable device and conveys the information for longitudinal data storage—including creating/appending to an established data record via a on the host computer (600) which maintains all test results across all testing systems. This data can be further post processed for continuous refinement of the correcting parameters, refinement of the testing protocols and other materials improvement research purposes.

Optionally in accordance with the various aspects of the present invention, a result can be printed out in (870) to provide the operator a copy of the test results. The operator for example, could be a maintenance specialist performing a diagnostic or periodic condition assessment test, for which the results could direct certain condition based maintenance actions. This information is the same information that is provided to the data display and the data storage. Optionally this report can be communicated via other media such as a digital memory card (such as an SD Card or other persistent removable memory device) or to other portable electronic devices such as a smart phone or data logging device.

The raw measurement data (760) is presented to the processing modules for evaluation. Data filtering module (810) is further explained in FIG. 4. Starting with a comparison against stored reference data (1010), which is previously established such as in FIG. 5 (990), is to determine if the data conforms to an expected range (e.g. if there was a null measurement or a highly unexpected measurement, such as applied when an incorrect test was performed). This would result in setting a flag in the Error State Detector (1020) such that there was an incorrect or inaccurate measurement. The Error would be queued for notification in the Error Display and Alerts (880) function, such as to an operator or maintenance specialist engaged in performing diagnostic or other analysis. In parallel or via selective determination, one or multiple filtering methods would be applied to the raw data, including the reference data to be evaluated including Neural Network filtering (1030), Fuzzy Logic Filtering (1040), Bayesian filtering (1050), Hidden Markov Model (1060) and Kalman (1070), which also could include reverse Kalman filtering as well.

The calculated output results from the data filtering are communicated to a real-time characteristic data extraction module (1080), which isolates the specific data components of the resulting measurement such as force onset, force maxima, force minima, acceleration moment, variation and time to return to baseline stability and other measures. The characteristic data extraction evaluates both the reference data against the filtered results and provides correlated evaluation of the parametric features.

Concurrently, each of the filtered data elements is compared (1090) against the last corrected filtered data (1100) (if any) across the filtered results to determine if the result can be further refined through continuing to apply filtering data correction by comparison of the enhanced filtering result (1200) to prior results. This evaluation also compares against stored reference data (1010) as well as the comparative data output (1090) which also evaluates against the raw measurement data previously acquired (760). The result is an evaluation of both the individual and combined adaptive filtering correction results of the data over a time series which provides a way to calculate a predictive value which improves the underlying measurement accuracy.

In the optimal correction decision module (1210) the comparative evaluation of the last result to the latest result coupled with the output comparative data (1090) is compared to determine if any differences in the result through additional filtering will measurably improve the correction. This direct correction and as well as reverse prediction techniques can be recursively applied across one or more filtering methods to goal-seek the optimal predicted correction. If in the comparison (1090) there is negligible change from the prior result, e.g. the data has converged across the optimal filtering and data correction process, the corrected data is then sent to the association module (820) along with the last output comparative data result (1200) which can be either the enhanced data result via data improvement filtering, or the raw measurement, along with the characteristic extracted data (1080) as well as any error condition (1020). When the data residual is minimized this equates to the minimal prediction error.

Such early detection, preventative measures such as identifying “weak” components, will improve the overall outcomes as well as mitigate potential for downstream operating failure, outages and costly repairs. This has applicability to a number of stake holders including equipment that may be operated in austere environments—such as a remote location, or applied in a defense/security application where repair and replacement are costly—or not very feasible. Such equipment with detected issues would not be deployed as the risk of readiness and reliability in the field may be lower.

This invention further teaches a cumulative process to determine expected longevity across use case/parameters to provide a prediction of longevity of a component. This can be helpful in making a deploy/no-deploy decision for a given platform that incorporates type of detection methodology and provides this operational insight. As well, traditional preventative maintenance, such as based on intervals, can be replaced with a much more precise, and cost effective approach that only performs maintenance, repair/replacement on the condition when needed.

This invention also can help in providing risk assessments prior to implementing a given platform. The toolsets driven by this invention can also propel more precise and accurate protocols for designing better components plans and provide continuous assessment and immediate feedback for improvement due to the encountered operational life. A byproduct of this invention will also allow for the objective measurement and assessment of degree of device resilience, which could help in determining if an individual component or system would be able to safely perform over a given forward anticipated timeframe.

The present invention would allow this invention's practitioners to move away from present life cycle management regimes such as a “regular interval” maintenance models towards a model where devices are maintained based on a likelihood of failure as detected by the measured device resilience and degradation factors beyond just indicated age (e.g. when manufactured) and duty cycle/usage of the component. This has implications in terms of stockpiling spare parts and related logistics required for traditional regular maintenance cycles. Instead, a more “just-in-time” spare parts inventory model can be used, based on a predicted impending failure of devices. A statistical template of age and usage curves can be derived leveraging the present and prior art of invasive and non-invasive measurements of performance, including accelerated and destructive testing. The “weak” circuits in the microelectronic systems accentuate these effects to allow detection on an individual device level.

We note that in present and prior art, manufactured microelectronics die are graded and tested for speed, performance, etc., and subsequently marked as sold as a part that operates within a spec. Parts in different performance/speed “bins” can be charged for different prices, to allow a maximum revenue derived from the manufacturing variations of the devices. The “weak” circuits that are a part of the present invention can also be used to complement the “grading” of components.

For certain components designed for very high-reliability applications as well as extreme environments, difficult to replace (such as embedded in medical implanted devices), deployed into space, used deep underwater, or to operate in very high and very low temperatures and pressures, even greater margins are introduced into components. Further, there is more intensive testing and validation of components, etc. Though the application of this invention, the emplacement of the early detection capabilities can help in developing more effective products as well as provide for early categorization of a batch of components to ‘grade’ their relative resilience. In this case, the highest, most resilient components could be sub-selected for the most critical applications and environments. Further, the present invention can be used to detect operational stress, for example, detecting extended and prolonged operation of a satellite under extreme temperature and radiation environments, to give early feedback on the need to switch to a backup system or to plan for an in-space mission for a very targeted repair since the impending failure mode and device has been presumably predictively identified.

The present invention overcomes deficiencies associated with conventional approaches. First, conventional approaches do not accommodate the natural manufacturing variations that each individual component expresses. These are due to minute variations in both the manufacturing process as well as provide for a robust way to uniquely resolve the identity of an electronic component. The sensing measurement methodology of the present invention applies an ability to converge discrete orthogonal parasitic and non-parasitic sensor modes including a set of at least one parametric monitors such as current, and weak or threshold circuits that would fail as a device ages or degrades couple with a set of at least one unclonable functions versus a single methodology that cannot only accomplish this but also assert a device's unique identity. This coupled with the baseline of the unclonable functions which assert the correcting and other vectors can help to quantify not only a component's “starting point' but as well aver the validity and identity of the component.

The present invention further improves upon prior techniques in a number of ways including integrating the measurements of multiple dimensions of parameters, establishing and accumulating longitudinal monitoring, and a correction vector/factor and compares both individually and combined measurements to aver device condition such as from a reference starting point to establish a component's age, or relative age against a set of devices. Further, through the introduction and application of one or more predictive algorithmic correction(s), such as Kalman filtering, hidden Markov modeling and other techniques across a longitudinal time-series sequence of measurements, can improve the fidelity and correct for inaccuracies in the acquisition and measurement of a specific measurement or sequence of measurements. The prior art “Physics of Failure” approach does not anticipate or accommodate such individual device ‘starting point’ differences (e.g. each and every electronic component is in reality is commencing its life from a different baseline, and as such will have by definition achieve a different life-span, just as people have varying lifespans due to many factors. Such correction methodologies accommodates this natural variation and other factors in the testing process including the measurement of the calculated expected values (based on overall component measured behavior) as compared to a specific component or family of similar components against such metrics.

With conventional measurement techniques, such as expressed by the University of Maryland's CALCE, have been applied for detecting a device's age by categorizing measurements such as time-delays inside circuit paths as a way to determine its relative age across a set of components. In effect the present invention provides a counter intuitive approach by applying the underlying principle that no two devices are exactly the same, and therefore will have different life spans due not only to usage, but by their inherent and unique variations. As no two devices will age nor behave exactly the same, it is through concomitant measurements of device condition, along with algorithmic corrected calculations that can improve the fidelity of the condition measurements, not just the assess the apparent age of a device

To provide an enhanced understanding beyond a static examination to determine device condition and subsequent performance and longevity, the present invention provides a number of dimensions for non-invasive, in-operational measurements of individual and combined elements of the spectrum of circuits that has a high variability due to manufacturing variations, including but not limited to delay circuits such as ring oscillators and bi-stable circuits such as back-to-back inverters, latches, etc. The present invention improves upon prior art in a number of ways including establishing a dynamically programmatic protocols via establishing a determining process to indicate the proposed set(s) and sequencing of tests for measurement and thus the reduction or elimination of certain tests that are not necessarily relevant to perform at each time the device is measured or tested during its lifetime to enhance the resulting analysis and reduce the ‘time to test’ for each component.

As well in the case of repeated, longitudinal testing, this invention seeks to provide a more robust, multi-dimensional measurement approach. The present invention starts with the expectation that each device is slightly different. This inherent difference establishes any given component has to be first established, and this is accomplished through the use of unclonable functions. The approach provides early insight(s) and input to the resilience, stability, longevity and lifetime of a component. Coupled with other multi-dimensional measurement means enables an improved granularity of the measurement of a component's life.

The invention instantiates itself onto the component in the form of “blocks” of circuits and logic, which can be possibly manipulated via firmware and/or software on the component, that can be queried by a testing framework and as a algorithmic processing and data management platform residing outside the component. The resulting measured information is communicated to a back-end processor that lies outside the component that evaluates the testing information to include historic/longitudinal measurements as well as intra and inter component measurements of similar elements. The cumulative data established improves as there is more data developed through the measurements and processing, which will allow for more precise device understanding as the population of components and measurements of these components grows over time.

The invention improves the understanding of a device's longevity to an individual level, versus at a crude population level such as a mean-time-between-failure which doesn't maintain periodic understanding of individual device performance. Another important distinction is the understanding that the life-curve of any given device, for reasons described above are not exactly the same, as a device could start at a different starting point, and thus result in a different resilience, lifetime, and failure mode. This invention anticipates this inherent component variability that is introduced due to the multitude of variables encountered in the fabrication process. There is further variability in a component's usage, including environment, duty cycle, and exposure to conditions adverse to the component. In sum, no two components will behave exactly the same way, and thus the need to accommodate this variability in the condition assessment framework.

Multiple modalities and measurements interspersed across a component provide for a more effective assessment and evaluation. The invention uses the manufacturing uniqueness of a device as a starting point in helping to predict the failure modes associated with the manufacturing instance of that device.

In addition, this invention can further detect predicted failure through the aggregated correlation of derived compensating error vectors from a set of at least one measurement means. The process to derive the tests needed to be conducted and the measurements performed may be variable based on the computation of a set of at least one of the context of the testing, and other information which can include a number of factors including, for example an error correction compensating vector.

The present invention is further enhanced through the combining of at least one of a set of test cells that are across a device in such a way that multiple tests are concurrently performed, which that initially establish the unique device's starting life-point or baseline and enables subsequent longitudinal comparison over time. This improves upon the prior approaches which require the discrete measurement in component isolation; although useful, fails to provide the insights of the component's failure path and the specific resilience, remaining useful life and other parameters.

Integrating the multiple measurement points provides cumulative benefits to the invention. This allows the diagnostic advantage to concomitantly improve the fidelity of the individual measurements as well as to provide a means to derive converging diagnostic results. Through the understanding of the multiple simultaneous measurements, this improves the detection, including the predicted predisposition to failure, and lifetime calculated, based not just on the weakest circuit (per Xie and Pecht). Through measurement can span across known and expected behaviors, the degree of variance across the dimensions can be more closely analyzed, and understood with introduction of at least one, potential multiple, correlations to the corrective error vector or vectors.

Integrating the individual specific tests also improves the underlying data fidelity and supports the diagnostic confirmation of the other conducted and subsequently correlated individual tests. These measures can also be applied to direct specific algorithmic post processing including data filtering to refine and to converge individual test analyses to improve the net accuracy. As each test performed not only is subjected to a series of individual specified computationally calculated determined analysis, but the resulting outputs can be used to provide analysis to provide input into the prediction of the acceptability and resulting quality of the anticipated test and test result. This can be used to provide a mechanism to computationally correct (such as applied by error correction techniques as taught across numerous applications from video and audio coding, etc.) and other methods such as applied by Kalman filtering or a hidden Markov, Bayesian or other such mathematical approaches.

The present invention also incorporates a control program that self-calibrates, develops, directs and integrates not only the determination of the testing and testing sequence process, but as well verifies and processes the test measurement data collected using both individual and combined measurements as described below. The control program also determines if the data is of sufficient measurement by comparing against previously acquired test data from the component. The control program also evaluates and maintains the underlying data values, testing protocols and measurement methodologies to process and determine if the computed analysis deviates outside the expected value ranges and therefore provides an indication of potential early failure or reduced component performance.

Additionally this invention contemplates gaining additional understanding based on comparative analysis of prior tests both on a longitudinal basis such as a time series of tests conducted on a periodic basis as well as on a comparative basis against comparable similar populations of tests performed across confirmed such analysis in similar components. This enables that the class of testing can be applied across multiple similar components using a common IP block of the testing elements for a given fabrication process. In effect, any device produced that contained this testing block would derive common insights on the reliability, age, resilience measurements, which can enable with less data sampling a more insightful understanding of a component within a family.

The approach of the present invention overcomes a number of limitations of traditional methods including invasive/destructive methods by integrating across a set of tests and providing comparative (including longitudinal and associative population referential comparatives) in a single measurement framework that conducts measurements across a family of components. This allows the component to be used and measured versus used or measured.

Through the use and concurrent evaluation of several variables across the testing protocol, this assessment approach provides for concurrent error measurement and correction and as well calculating converging insight into various device conditions.

Further, the present invention will allow stakeholders including a non-invasive longitudinal tool to gain insight into both a specific component, and other devices fabricated by the same processes. The invention further lowers the cost of testing and improves the fidelity of the measured results.

The system is as well adaptive and allows the introduction of new tests, or the streamlining and combination of measurements and tests based on acquired data. The foregoing are illustrative embodiments of the present invention, and are not intended to limit or define the scope of the present invention. The above description is intended to be illustrative, and not restrictive. Although the examples given include specifics, they are intended as illustrative of only certain possible applications of the present invention. The examples given should only be interpreted as illustrations of some of the applications of the present invention, and the full scope of the present invention should be determined by the appended claims and their legal equivalents.

Therefore, it is to be understood that the present invention may be practiced other than as specifically described herein. It is also to be understood that the terminology used herein is for the purpose of describing particular embodiments only, and is not intended to be limiting. The scope of the present invention as disclosed and claimed should, therefore, be determined with reference to the knowledge of one skilled in the art and in light of the disclosures presented above.

While the present invention has been described with reference to the specific applications thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto. Although various aspects of the present invention are set out in the independent claims, other aspects of the invention comprise any combination of the features from the described embodiments and/or the dependent claims with the features of the independent claims, and not the solely the combination explicitly set out in the claims.

The various aspects of the present invention may be implemented in software, hardware, application logic, or a combination of software, hardware, and application logic. The software, application logic and/or hardware may reside on a server, an electronic device, or a service. If desired, part of the software, application logic and/or hardware may reside on an electronic device, part of the software, application logic and/or hardware may reside on a server.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

Unless defined otherwise, all technical and scientific terms used herein have the same meaning as commonly understood by one of ordinary skill in the art to which this invention belongs. Any methods and materials similar or equivalent to those described herein can also be used in the practice or testing of the present invention.

All publications and patents cited in this specification are incorporated herein by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims. As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

In accordance with the teaching of the present invention and certain embodiments, a program or code may be noted as running on a computing device. A computing device is an article of manufacture. Examples of an article of manufacture include: a server, a mainframe computer, a mobile telephone, a multimedia-enabled smartphone, a tablet computer, a personal digital assistant, a personal computer, a laptop, a set-top box, an MP3 player, an email enabled device, a web enabled device, or other special purpose computer each having one or more processors (e.g., a Central Processing Unit, a Graphical Processing Unit, or a microprocessor) that is configured to execute a computer readable program code (e.g., an algorithm, hardware, firmware, and/or software) to receive data, transmit data, store data, or perform methods. The article of manufacture (e.g., computing device) includes a non-transitory computer readable medium having a series of instructions, such as computer readable program steps encoded therein. In certain embodiments, the non-transitory computer readable medium includes one or more data repositories.

By way of illustration and not limitation, the computing device can include: an input/output means, such as a keyboard, a mouse, a stylus, touch screen, a camera, a scanner, or a printer; a processor; a non-transitory computer readable medium including at least one instruction/task or a series of instructions, such as computer readable program with steps encoded therein.

The non-transitory computer readable medium includes corresponding computer readable program code and may include one or more data repositories. The processors access the computer readable program code encoded on the corresponding non-transitory computer readable mediums and execute one or more corresponding instructions. Other hardware and software components and structures are also contemplated.

In accordance with various aspects of the present invention and in certain embodiments, a data repository is referenced. The data repositories comprises one or more hard disk drives, tape cartridge libraries, optical disks, combinations thereof, and/or any suitable data storage medium, storing one or more databases, or the components thereof, in a single location or in multiple locations, or as an array such as a Direct Access Storage Device (DASD), redundant array of independent disks (RAID), virtualization device, etc.

In accordance with various aspects of the present invention and in certain embodiments, the data repository is structured by a database model, such as a relational model, a hierarchical model, a network model, an entity-relationship model, an object-oriented model, a combination thereof, or the like. For example, in certain embodiments, the data repository is structured in a relational model that stores data regarding a computer-aided design.

In accordance with various aspects of the present invention and in certain embodiments and in accordance with any aspect of the present invention, computer readable program code is encoded in a non-transitory computer readable medium of the computing device. The processor, in turn, executes the computer readable program code to create or amend an existing computer-aided design using a tool. In other embodiments, the creation or amendment of the computer-aided design is implemented as a web-based software application in which portions of the data related to the computer-aided design or the tool or the computer readable program code are received or transmitted to a computing device of a host.

In certain embodiments based on the various aspects of the present invention, reference is made to communication between two electronic devices or components. The communication fabric may include any means for communication and, includes, for example: wired communication on a local bus, communication throughout a computer device, the Internet, an intranet, an extranet, a storage area network (SAN), a wide area network (WAN), a local area network (LAN), a virtual private network, a satellite communications network an interactive television network, any combination of the foregoing, and the like. In certain embodiments, the communication fabric contains either or both wired or wireless connections for the transmission of signals including electrical connections, magnetic connections, or a combination thereof. Examples of these types of connections include: radio frequency connections, optical connections, telephone links, a Digital Subscriber Line, or a cable link. Moreover, communication fabric utilize any of a variety of communication protocols, such as Transmission Control Protocol/Internet Protocol (TCP/IP), for example. In certain embodiments, the communication fabric includes one or more switches.

In accordance with various aspects of the present invention and in certain embodiments, the processor accesses corresponding Application Program Interfaces (APIs) encoded on the corresponding non-transitory computer readable medium and execute instructions to electronically communicate with computing device during a computer-aided session, for example. Similarly, the processor accesses the computer readable program code, encoded on the non-transitory computer readable medium, and executes an instruction to electronically communicate with the computing device via the respective communication fabric. In certain embodiments, the computing device 110 provides access to the computing devices to execute the computer readable program code via a Software as a Service (SaaS).

In accordance with various aspects of the present invention and in certain embodiments, the system includes a hardware-based module (e.g., a digital signal processor (DSP), a field programmable gate array (FPGA)) and/or a software-based module (e.g., a module of computer code, a set of processor-readable instructions that are executed at a processor). In some embodiments, one or more of the functions associated with the system is performed, for example, by different modules and/or combined into one or more modules locally executable on one or more computing devices.

Accordingly, the preceding merely illustrates the various aspects and principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

What is claimed is:

1. A method for monitoring an electronic component based on selecting a set of measurements, the method comprising the steps of:
identifying the set of measurements based on parameters related to the monitoring of the component;
performing the set of measurements to provide measurement data;
evaluating the measurement data to determine if any measurement from the set of measurements can be improved by providing data filtering and data correction; and
processing the measurement data for the set of measurements against a set of corresponding reference measurements to provide analysis of the monitoring.

2. The method of claim 1 further comprising the step of storing the measurement data.

3. The method of claim 1 further comprising the step of communicating the data measurements.

4. The method of claim 3, wherein the communication is through a display.

5. The method of claim 3, wherein the communication is wireless.

6. The method of claim 1, wherein at least one measurement is derived from a physically unclonable function measurement.

7. The method of claim 1, wherein the measurement data is communicated to a computer and the computer evaluates and validates the expected conformance of the measurement data as suitable within acceptable range limits from which a determination can be made that the measurement data is acceptable or not acceptable for processing and evaluation.

8. The method of claim 1, wherein the set of measurements includes a measurement for a weak circuits.

9. The method of claim 1, wherein the step of performing includes improved analytic results to provide corrected values for the measurement data.

10. The method of claim 1, wherein the step of evaluating includes improved analytical results based on applying Kalman filtering techniques.

11. The method of claim 1, wherein the step of evaluating includes improved analytical results based on applying Bayesian filtering techniques.

12. The method of claim 1, wherein the step of evaluating includes improved analytical results based on applying hidden-Markov filtering techniques.

13. The method of claim 1, wherein the step of evaluating includes improved analytical results based on applying fuzzy-logic analysis techniques.

14. The method of claim 1, wherein the step of evaluating includes improved analytical results based on applying neural-network analysis techniques.

15. The method of claim 1 further comprising the step of comparing and adjusting expected baseline data such as predicted calculated changes in performance and resulting measurements are correlated due to component age.

16. The method of claim 1 further comprising the step of comparing and adjusting expected baseline data such as predicted calculated changes in performance and resulting measurements are correlated due to confirmed component condition.

17. The method of claim 1 further comprising the step of applying direct measurement and predicted calculated values for tracking longitudinal changes.

18. The method of claim 1 further comprising the step of algorithmic filtering using multiple sensor inputs to provide corrected values across measurement domains.

19. The method of claim 1 further comprising the step of processing at least one sensor input to compute improved analytic results based on Bayesian analytic techniques across longitudinal changes.

20. The method of claim 1 further comprising the step of processing at least one sensor input to compute improved analytic results based on hidden-Markov Filtering techniques across longitudinal changes.

21. The method of claim 1 further comprising the step of processing at least one sensor input to compute improved analytic results based on fuzzy logic analysis techniques across longitudinal changes.

22. The method of claim 1 further comprising the step of processing at least one sensor input to compute improved analytic results based on neural network analysis techniques across longitudinal changes.

23. The method of claim 1 further comprising the step of calculating expected measurement results based on a time series of a set of at least one performance measurements as adjusted for factors including age, condition, duty cycle, known exposure, and other documented factors.

24. The method of claim 1 further comprising the steps of:
applying direct and calculated values for tracking and calculating the time series expected rates of change versus observed rates of change of any single or multiple sensing dimensions; and
calculating the expected divergence or convergence across multiple sensor time series data of anticipated and expected measured value changes versus unexpected changes.
